(19) United States
(12) Patent Application Publication
(10) Pub. No.: US 2023/0291387 A1
(43) Pub. Date: Sep. 14, 2023

(54) PIEZOELECTRIC FILTER

(71) Applicants: Takahiro WAKASUGI, Tokyo (JP); Yasuyuki SUDO, Tokyo (JP)

(72) Inventors: Takahiro WAKASUGI, Tokyo (JP); Yasuyuki SUDO, Tokyo (JP)

(73) Assignee: MITSUMI ELECTRIC CO., LTD., Tokyo (JP)

(21) Appl. No.: 18/178,807

(22) Filed: Mar. 6, 2023

(30) Foreign Application Priority Data
Mar. 11, 2022 (JP) 2022-038500

(51) Int. Cl. H03H 9/56

(52) U.S. Cl. CPC H03H 9/568

(57) ABSTRACT

A technique is provided herein whereby the size of piezoelectric filters can be reduced. A piezoelectric filter according to one aspect of the present disclosure has: a first substrate having a first main surface; a second substrate having a second main surface facing the first main surface; and a ladder circuit of Nth order, including N piezoelectric resonators, N being an integer of 3 or greater. In this piezoelectric filter, the first-order to Mth-order piezoelectric resonators included in the ladder circuit are formed on the first main surface, M being an integer from 1 to N−1, inclusive, and the (M+1)th-order to Nth-order piezoelectric resonators included in the ladder circuit are formed on the second main surface.

### CROSS-REFERENCE TO RELATED APPLICATION

The present application is based on and claims priority under 35 U.S.C. § 119 to Japanese Patent Application No. 2022-038500, filed on Mar. 11, 2022, the contents of which are incorporated herein by reference in their entirety.

### BACKGROUND OF THE INVENTION

### 1. Field of the Invention

The present disclosure relates to the piezoelectric filter.

### 2. Description of the Related Art

A ladder filter is known, in which series resonators and parallel resonators are formed in an L shape. As an example of a ladder filter, a structure in which series resonators are formed on a first substrate and parallel resonators are formed on a second substrate is disclosed (see, for example, Patent Document 1).

### RELATED-ART DOCUMENT

### Patent Document

[Patent Document 1] Japanese Unexamined Patent Application Publication No. 2016-018846

### SUMMARY OF THE INVENTION

In the above structure, a larger number of terminals are provided on the first substrate and the second substrate. The larger the number of terminals, the larger the size of the ladder filter.

The present disclosure therefore provides a technique for reducing the size of a piezoelectric filter.

In one aspect of the present disclosure, a piezoelectric filter is provided that has: a first substrate having a first main surface; a second substrate having a second main surface facing the first main surface; and a ladder circuit of Nth order, including N piezoelectric resonators, N being an integer of 3 or greater, and, in this piezoelectric filter, first-order to Mth-order piezoelectric resonators included in the ladder circuit are formed on the first main surface, M being an integer from 1 to N−1, inclusive, and (M+1)th-order to Nth-order piezoelectric resonators included in the ladder circuit are formed on the second main surface.

According to the present disclosure, the size of a piezoelectric filter can be reduced.

### BRIEF DESCRIPTION OF THE DRAWINGS

FIG. 1 is a circuit diagram that shows a piezoelectric filter according to a first embodiment;

FIG. 2A and FIG. 2B are schematic diagrams that each show arrangement of elements in the piezoelectric filter according to the first embodiment;

FIG. 3 is a circuit diagram that shows a piezoelectric filter according to a reference example 1;

FIG. 4A and FIG. 4B are schematic diagrams that each show arrangement of elements in the piezoelectric filter according to reference example 1;

FIG. 5 is a circuit diagram that shows a piezoelectric filter according to a reference example 2; and

FIG. 6 is a circuit diagram that shows a piezoelectric filter according to a second embodiment.

### DESCRIPTION OF THE EMBODIMENTS

Non-limiting example embodiments of the present disclosure will be described below with reference to the accompanying drawings. Throughout the accompanying drawings, the same or corresponding members or parts are assigned the same or corresponding reference numerals, and overlapping description will be omitted.

### First Embodiment

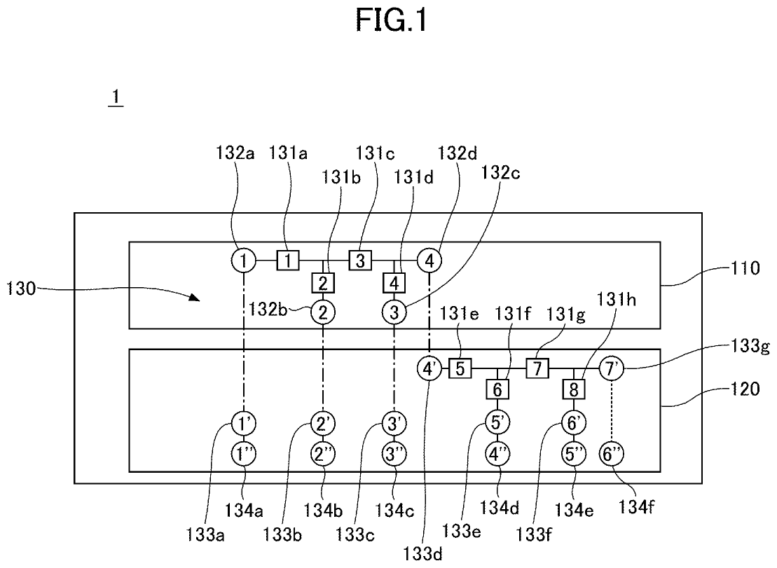

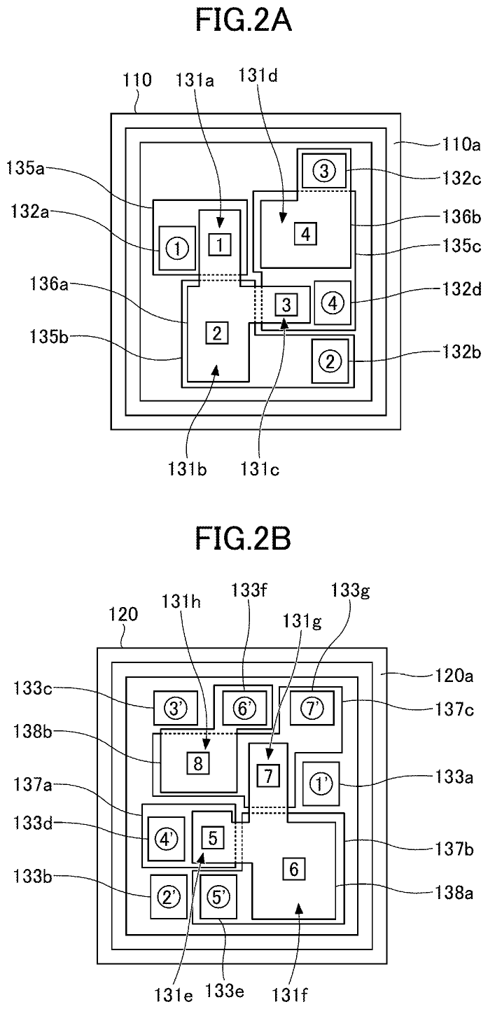

A piezoelectric filter 1 according to a first embodiment will be described with reference to FIG. 1 and FIGS. 2A and 2B. FIG. 1 is a circuit diagram that shows the piezoelectric filter 1 according to the first embodiment. FIG. 2A and FIG. 2B are schematic diagrams that show arrangement of elements in the piezoelectric filter 1 according to the first embodiment. FIG. 2A shows a first substrate 110 viewed from the second substrate 120 side, and FIG. 2B shows a second substrate 120 viewed from the first substrate 110 side.

The piezoelectric filter 1 is a ladder filter formed with series resonators and parallel resonators arranged in an L shape. The piezoelectric filter 1 may be, for example, a bandpass filter. The piezoelectric filter 1 has a first substrate 110, a second substrate 120, and a ladder circuit 130.

The first substrate 110 has a flat rectangular shape. The first substrate 110 has a first main surface 110a. Elements that constitute the ladder circuit 130, which will be described later, are formed on the first main surface 110a.

The second substrate 120 has a flat rectangular shape of approximately the same size as the first substrate 110. The second substrate 120 has a second main surface 120a. The second main surface 120a faces the first main surface 110a. Elements that constitute the ladder circuit 130, which will be described later, are formed on the second main surface 120a. The first substrate 110 and the second substrate are arranged such that the first main surface 110a and the second main surface 120a face each other, and are joined via first main surface terminals 132a to 132d and second main surface terminals 133a to 133d, which will be described later.

The ladder circuit 130 is eighth order and includes eight piezoelectric resonators 131a to 131h. The ladder circuit 130 thus has piezoelectric resonators 131a to 131h, first main surface terminals 132a to 132d, second main surface terminals 133a to 133g, and outer connecting terminals 134a to 134f. Hereinafter, for ease of explanation, the piezoelectric resonators 131a to 131h may be collectively referred to as “piezoelectric resonators 131,” the first main surface terminals 132a to 132d may be collectively referred to as “first main surface terminals 132,” and the second main surface terminals 133a to 133g may be collectively referred to as “second main surface terminals 133.”

The piezoelectric resonators 131a to 131h each have a lower electrode, a piezoelectric film, and an upper electrode. The piezoelectric film is sandwiched between the lower electrode and the upper electrode. In plan view normal to the first main surface 110a or the second main surface 120a, the part where the lower electrode, the piezoelectric film, and the upper electrode overlap is the size of the piezoelectric resonators 131a to 131h. The piezoelectric resonators 131a to 131h are BAW (Bulk Acoustic Wave) resonators. The BAW resonators may be FBARs (Film Bulk Acoustic Resonators) or SMRs (Solid Mounted Resonators). The lower electrode and the upper electrode are made of metal such as molybdenum (Mo), tungsten (W), titanium (Ti), gold (Au), platinum (Pt), ruthenium (Ru), and aluminum (Al). The piezoelectric film is made of, for example, aluminum nitride (AlN), lead zirconate titanate (PZT), or zinc oxide (ZnO).

The piezoelectric resonators 131a to 131d are formed on the first main surface 110a. The piezoelectric resonators 131a and 131c are series resonators. The piezoelectric resonators 131b and 131d are parallel resonators. In plan view normal to the first main surface 110a, the size of the piezoelectric resonators 131a and 131c is smaller than the size of the piezoelectric resonators 131b and 131d. The piezoelectric resonators 131a to 131c have a common upper electrode 136a, and are electrically connected via the upper electrode 136a. The piezoelectric resonators 131c and 131d have a common lower electrode 135c, and are electrically connected via the lower electrode 135c.

The piezoelectric resonator 131a is structured such that a piezoelectric film (not shown) is sandwiched between a lower electrode 135a and an upper electrode 136a. The piezoelectric resonator 131a is electrically connected with the first main surface terminal 132a via the lower electrode 135a.

The piezoelectric resonator 131b is structured such that a piezoelectric film (not shown) is sandwiched between a lower electrode 135b and the upper electrode 136a. The piezoelectric resonator 131b is electrically connected with the first main surface terminal 132b via the lower electrode 135b.

The piezoelectric resonator 131c is structured such that a piezoelectric film (not shown) is sandwiched between a lower electrode 135c and the upper electrode 136a. The piezoelectric resonator 131c is electrically connected with the first main surface terminal 132d via the lower electrode 135c.

The piezoelectric resonator 131d is structured such that a piezoelectric film (not shown) is sandwiched between the lower electrode 135c and an upper electrode 136b. The piezoelectric resonator 131d is electrically connected with the first main surface terminal 132c via the upper electrode 136b.

The piezoelectric resonators 131e to 131h are formed on the second main surface 120a. The piezoelectric resonators 131e and 131g are series resonators. The piezoelectric resonators 131f and 131h are parallel resonators. In plan view normal to the second main surface 120a, the size of the piezoelectric resonators 131e and 131g is smaller than the size of the piezoelectric resonators 131f and 131h. In plan view normal to the second main surface 120a, the piezoelectric resonators 131e to 131h have a part where they overlap with the piezoelectric resonators 131a to 131d. The piezoelectric resonators 131e to 131g have a common upper electrode 138a, and are electrically connected via the upper electrode 138a. The piezoelectric resonators 131g and 131h have a common lower electrode 137c, and are electrically connected via the lower electrode 137c.

The piezoelectric resonator 131e is structured such that a piezoelectric film (not shown) is sandwiched between a lower electrode 137a and the upper electrode 138a. In plan view normal to the second main surface 120a, the piezoelectric resonator 131e has a part where it overlaps with the piezoelectric resonator 131c. The piezoelectric resonator 131e is electrically connected with the second main surface terminal 133d through the lower electrode 137a.

The piezoelectric resonator 131f is structured such that a piezoelectric film (not shown) is sandwiched between a lower electrode 137b and the upper electrode 138a. In plan view normal to the second main surface 120a, the piezoelectric resonator 131f has a part where it overlaps with the piezoelectric resonator 131b. The piezoelectric resonator 131f is electrically connected with the second main surface terminal 133e via the lower electrode 137b.

The piezoelectric resonator 131g is structured such that a piezoelectric film (not shown) is sandwiched between the lower electrode 137c and the upper electrode 138a. In plan view normal to the second main surface 120a, the piezoelectric resonator 131g has a part where it overlaps with the piezoelectric resonator 131a. The piezoelectric resonator 131g is electrically connected with the second main surface terminal 133g via the lower electrode 137c.

The piezoelectric resonator 131h is structured such that a piezoelectric film (not shown) is sandwiched between the lower electrode 137c and an upper electrode 138b. In plan view normal to the second main surface 120a, the piezoelectric resonator 131h has a part where it overlaps with the piezoelectric resonator 131d. The piezoelectric resonator 131h is electrically connected with the second main surface terminal 133f via the upper electrode 138b.

The first main surface terminals 132a to 132d are formed on the first main surface 110a. The first main surface terminals 132a to 132d are electrically connected with the second main surface terminals 133a to 133d, respectively.

The second main surface terminals 133a to 133g are formed on the second main surface 120a. The second main surface terminals 133a to 133c and 133e to 133g are electrically connected with the outer connecting terminals 134a to 134f, respectively, via through electrodes (not shown) penetrating the second substrate 120.

The outer connecting terminals 134a to 134f are formed on the surface of the second substrate 120, which is opposite the second main surface 120a.

According to the piezoelectric filter 1 of the first embodiment described above, four piezoelectric resonators 131a to 131d out of eight piezoelectric resonators 131a to 131h are formed on the first substrate 110, and the other four piezoelectric resonators 131e to 131h are formed on the second substrate 120. By this means, it is possible to prevent unnecessary parts where no piezoelectric resonators or terminals are formed, from being formed on the first main surface 110a and the second main surface 120a. Consequently, the size of the piezoelectric effect filter 1 can be reduced. As a result of this, the number of piezoelectric filters 1 that can be produced from a unit wafer increases, so that the manufacturing cost can be reduced.

Also, according to the piezoelectric filter of the first embodiment, the first-order to fourth-order piezoelectric resonators 131a to 131d are formed on the first substrate 110, and the fifth-order to eighth-order piezoelectric resonators 131e to 131h are formed on the second substrate 120. By this means, the number of the first main surface terminals 132 and the second main surface terminals 133 can be reduced. To be more specific, the number of the first main surface terminals 132 is four, and the number of the second main surface terminals 133 is seven. When the number of terminals is reduced, the area that the first main surface terminals 132 occupy on the first main surface 110a and the area that the second main surface terminals 133 occupy on the second main surface 120a can be reduced.

Also, according to the piezoelectric filter of the first embodiment, the piezoelectric resonators 131a and 131c, which are series resonators, and the piezoelectric resonators 131b and 131d, which are parallel resonators, are formed on the first substrate 110. Also, the piezoelectric resonators 131e and 131g, which are series resonators, and the piezoelectric resonators 131f and 131h, which are parallel resonators, are formed on the second substrate 120. Also, series resonators are smaller in size than parallel resonators. By this means, the difference between the area that the piezoelectric resonators 131a to 131d occupy on the first main surface 110a and the area that the piezoelectric resonators 131e to 131h occupy on the second main surface 120a is reduced. That is, the piezoelectric resonators 131a to 131h are formed on the first substrate 110 and the second substrate 120 in a good balance. As a result of this, it is possible to prevent unnecessary parts from being formed on the first main surface 110a and the second main surface 120a.

Conventionally known are piezoelectric filters having a structure in which all piezoelectric resonators are formed on one substrate, and piezoelectric filters having a structure in which series resonators are formed on a first substrate and parallel resonators are formed on a second substrate.

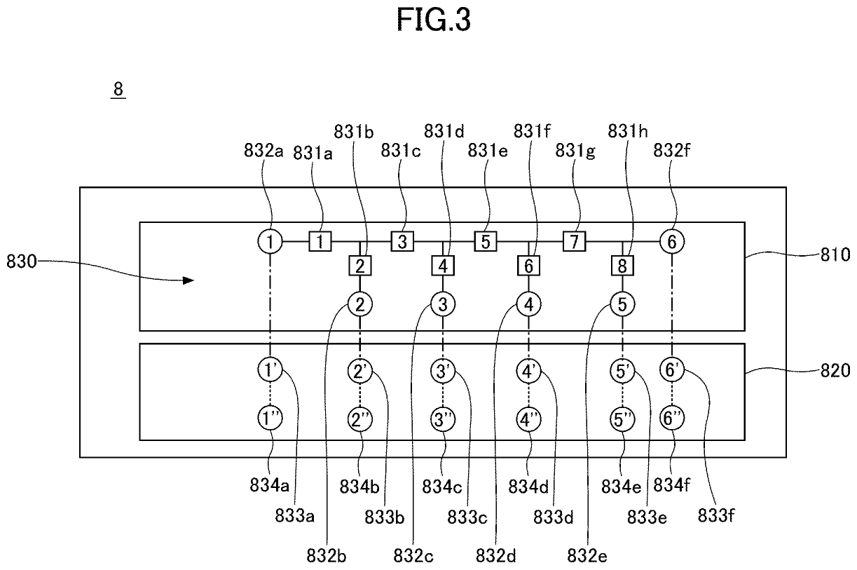

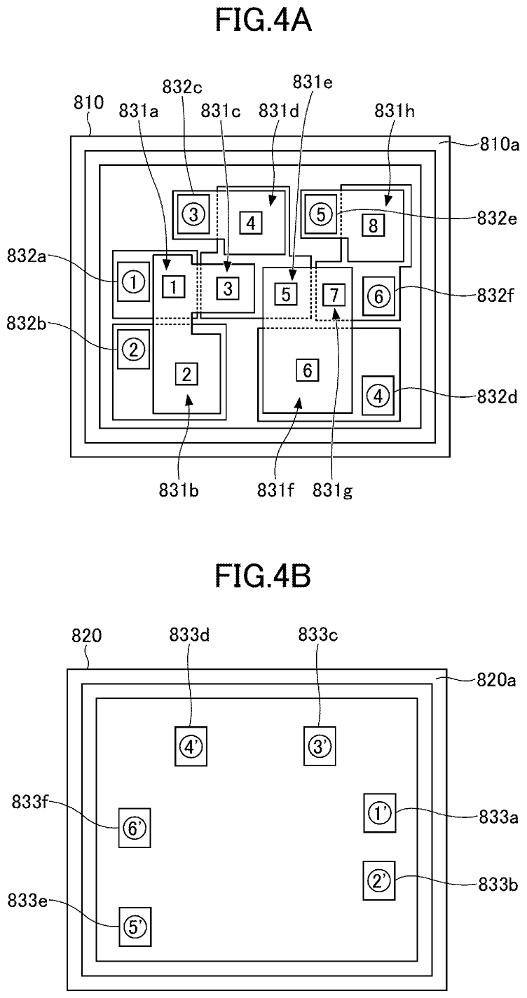

FIG. 3 is a circuit diagram that shows a piezoelectric filter 8 according to a reference example 1. FIGS. 4A and 4B are schematic diagrams that each show arrangement of elements in the piezoelectric filter 8 according to reference example 1. FIG. 4A shows a first substrate 810 viewed from the second substrate 820 side, and FIG. 4B shows a second substrate 820 viewed from the first substrate 810 side.

In the piezoelectric filter 8, all of piezoelectric resonators 831a to 831h are formed on the first substrate 810. The piezoelectric filter 8 has the first substrate 810, the second substrate 820 and a ladder circuit 830.

The first substrate 810 has a flat rectangular shape. The first substrate 810 has a first main surface 810a. Elements that constitute the ladder circuit 830, which will be described later, are formed on the first main surface 810a.

The second substrate 820 has a flat rectangular shape of approximately the same size as the first substrate 810. The second substrate 820 has a second main surface 820a. The second main surface 820a faces the first main surface 810a. Elements that constitute the ladder circuit 830, which will be described later, are formed on the second main surface 820a. The first substrate 810 and the second substrate are arranged such that the first main surface 810a and the second main surface 820a face each other, and are joined through first main surface terminals 832a to 832f and second main surface terminals 833a to 833f, which will be described later.

The ladder circuit 830 is eighth-order and includes eight piezoelectric resonators 831a to 831h. The ladder circuit 830 has piezoelectric resonators 831a to 831h, first main surface terminals 832a to 832f, second main surface terminals 833a to 833f, and outer connecting terminals 834a to 834f. Hereinafter, for ease of explanation, the piezoelectric resonators 831a to 831h may be collectively referred to as “piezoelectric resonators 831,” the first main surface terminals 832a to 832f may be collectively referred to as “first main surface terminals 832,” and the second main surface terminals 833a to 833f may be collectively referred to as “second main surface terminal 833.”

In the piezoelectric filter 8, all of the piezoelectric resonators 831a to 831h are formed on the first substrate 810, and no piezoelectric resonators are formed on the second substrate 820. Consequently, the size of the first substrate 810, on which all of the piezoelectric resonators 831a to 831h are formed, increases. As a result of this, the size of the piezoelectric filter 8 increases. Also, an unnecessary part where no piezoelectric resonators are formed and where only terminals are formed, is formed on the second substrate 820.

Also, in the piezoelectric filter 8, all of the piezoelectric resonators 831a to 831h are formed on the first substrate 810. By this means, the number of terminals increases. To be more specific, the number of first main surface terminals 832 is six, and the number of second main surface terminals 833 is six.

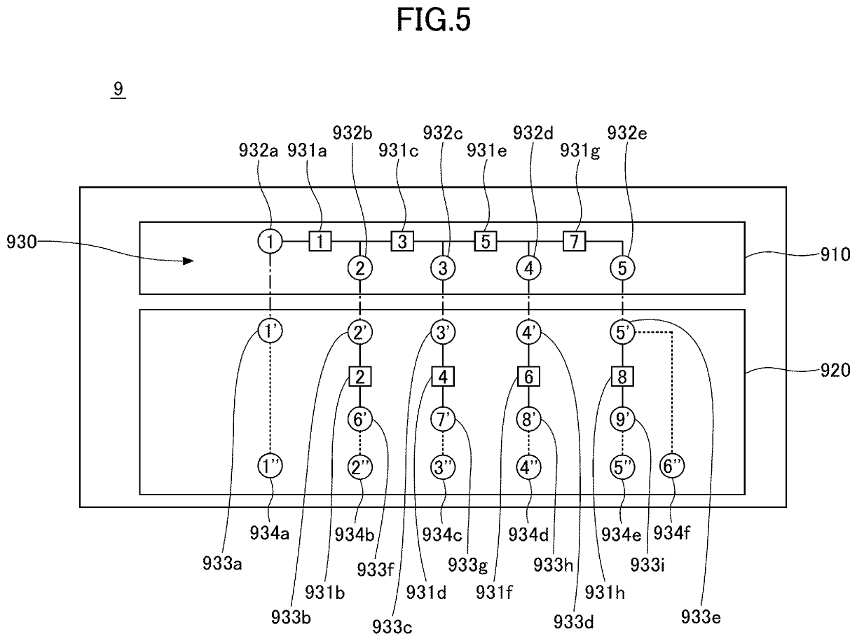

FIG. 5 is a circuit diagram that shows a piezoelectric filter 9 according to a reference example 2.

In the piezoelectric filter 9, piezoelectric resonators 931a, 931c, 931e, and 931g, which are series resonators, are formed on the first substrate 910, and piezoelectric resonators 931b, 931d, 931f, and 931h, which are parallel resonators, are formed on the second substrate 920. The piezoelectric filter 9 has the first substrate 910, the second substrate 920, and a ladder circuit 930.

The first substrate 910 has a flat rectangular shape. The first substrate 910 has a first main surface. Elements that constitute the ladder circuit 930, which will be described later, are formed on the first main surface.

The second substrate 920 has a flat rectangular shape of approximately the same size as the first substrate 910. The second substrate 920 has a second main surface. The second main surface faces the first main surface. Elements that constitute the ladder circuit 930, which will be described later, are formed on the second main surface. The first substrate and the second substrate 920 are arranged such that the first main surface and the second main surface face each other, and are joined via first main surface terminals 932a to 932e and second main surface terminals 933a to 933e, which will be described later.

The ladder circuit 930 is eighth order and includes eight piezoelectric resonators 931a to 931h. The ladder circuit 930 has piezoelectric resonators 931a to 931h, first main surface terminals 932a to 932e, second main surface terminals 933a to 933i, and outer connecting terminals 934a to 934f. Hereinafter, for ease of explanation, the piezoelectric resonators 931a to 931h may be collectively referred to as “piezoelectric resonators 931,” the first main surface terminals 932a to 932e may be collectively referred to as “first main surface terminals 932,” and the second main surface terminals 933a to 933i may be collectively referred to as “second main surface terminals 933.”

In the piezoelectric filter 9, the piezoelectric resonators 931a, 931c, 931e, and 931g, which are series resonators, are formed on the first substrate 910, and the piezoelectric resonators 931b, 931d, 931f, and 931h, which are parallel resonators, are formed on the second substrate 920. By this means, the number of terminals increases. To be more specific, the number of first main surface terminals 932 is five, and the number of second main surface terminals 933 is nine. Also, series resonators are smaller in size than parallel resonators. As a result, the area that the piezoelectric resonators 931b, 931d, 931f, and 931h occupy on the second main surface of the second substrate 920 becomes larger than the area that the piezoelectric resonators 931a, 931c, 931e, and 931g occupy on the first main surface of the first substrate 910. As a result of this, unnecessary parts may be formed on the first main surface of the first substrate 910.

### Second Embodiment

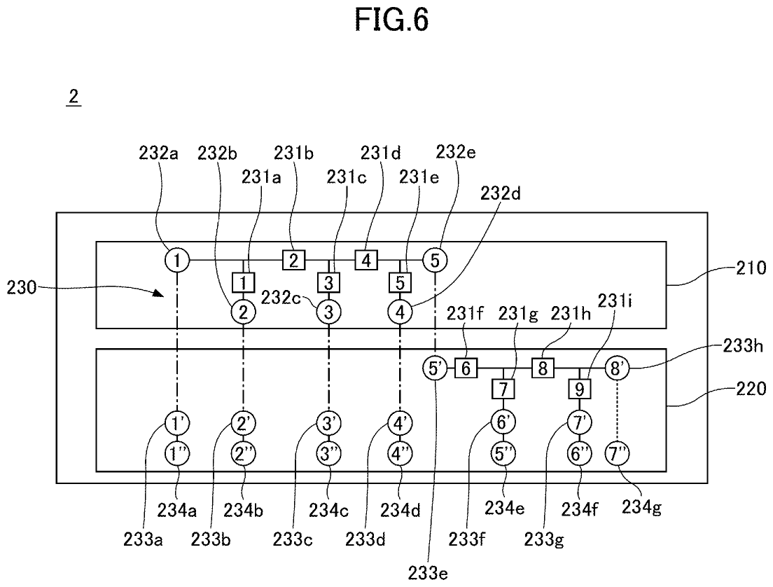

A piezoelectric filter 2 according to a second embodiment will be described with reference to FIG. 6. FIG. 6 is a circuit diagram that shows the piezoelectric filter 2 according to the second embodiment.

The piezoelectric filter 2 differs from the piezoelectric filter 1 in that it has a ladder circuit of ninth order including nine piezoelectric resonators 231a to 231i. Points that are different from the piezoelectric filter 1 will be mainly described below.

The piezoelectric filter 2 has a first substrate 210, a second substrate 220, and the ladder circuit 230.

The first substrate 210 has a flat rectangular shape. The first substrate 210 has a first main surface. Elements that constitute the ladder circuit 230, which will be described later, are formed on the first main surface.

The second substrate 220 has a flat rectangular shape of approximately the same size as the first substrate 210. The second substrate 220 has a second main surface. The second main surface faces the first main surface. Elements that constitute the ladder circuit 230, which will be described later, are formed on the second main surface. The first substrate and the second substrate 220 are arranged such that the first main surface and the second main surface face each other, and are joined via first main surface terminals 232a to 232e and second main surface terminals 233a to 233e, which will be described later.

The ladder circuit 230 is ninth order and includes nine piezoelectric resonators 231a to 231i. The ladder circuit 230 has piezoelectric resonators 231a to 231i, first main surface terminals 232a to 232e, second main surface terminals 233a to 233h, and outer connecting terminals 234a to 234g. Hereinafter, for ease of explanation, the piezoelectric resonators 231a to 231i may be collectively referred to as “piezoelectric resonators 231,” the first main surface terminals 232a to 232e may be collectively referred to as “first main surface terminals 232,” and the second main surface terminals 233a to 233h may be collectively referred to as “second main surface terminals 233.”

The piezoelectric resonators 231a to 231i each have a lower electrode, a piezoelectric film, and an upper electrode. The piezoelectric film is sandwiched between the lower electrode and the upper electrode. In plan view normal to the first main surface or the second main surface, the part where the lower electrode, the piezoelectric film, and the upper electrode overlap is the size of the piezoelectric resonators 231a to 231i. The piezoelectric resonators 231a to 231i are BAW resonators. The BAW resonators may be FBARs, or may be SMRs. The lower electrode and upper electrode are formed of metal such as Mo, W, Ti, Au, Pt, Ru, and Al. The piezoelectric film is made of AlN, PZT, and ZnO, for example.

The piezoelectric resonators 231a to 231e are formed on the first main surface. The piezoelectric resonators 231b and 231d are series resonators. The piezoelectric resonators 231a, 231c, and 231e are parallel resonators. In plan view normal to the first main surface, the size of the piezoelectric resonators 231a, 231c, and 231e is smaller than the size of the piezoelectric resonators 231b and 231d.

The piezoelectric resonators 231f to 231i are formed on the second main surface. The piezoelectric resonators 231f and 231h are series resonators. The piezoelectric resonators 231g and 231i are parallel resonators. In plan view normal to the second main surface, the size of the piezoelectric resonators 231f and 231h is smaller than the size of the piezoelectric resonators 231g and 231i. In plan view normal to the second main surface, the piezoelectric resonators 231f to 231i have a part where they overlap with the piezoelectric resonators 231a to 231e.

The first main surface terminals 232a to 232e are formed on the first main surface. The first main surface terminals 232a to 232e are electrically connected with the second main surface terminals 233a to 233e, respectively.

The second main surface terminals 233a to 233h are formed on the second main surface. The second main surface terminals 233a to 233d and 233f to 233h are electrically connected with the outer connecting terminals 234a to 234g, respectively, via through electrodes (not shown) penetrating the second substrate 220.

The outer connecting terminals 234a to 234g are formed on the surface of the second substrate 220, which is opposite the second main surface.

According to the piezoelectric filter 2 of the second embodiment described above, five piezoelectric resonators 231a to 231e out of the nine piezoelectric resonators 231a to 231i are formed on the first substrate 210, and the other four piezoelectric resonators 231f to 231i are formed on the second substrate 220. By this means, it is possible to prevent unnecessary parts where no piezoelectric resonators or terminals are formed, from being formed on the first main surface and the second main surface. Consequently, the size of the piezoelectric effect filter 2 can be reduced. As a result of this, the number of piezoelectric filters 2 that can be produced from a unit wafer increases, so that the manufacturing cost can be reduced.

Also, according to the piezoelectric filter of the second embodiment, the first-order to fifth-order piezoelectric resonators 231a to 231e are formed on the first substrate 210, and the sixth-order to ninth-order piezoelectric resonators 231f to 231i are formed on the second substrate 220. By this means, the number of the first main surface terminals 232 and the second main surface terminals 233 can be reduced. To be more specific, the number of the first main surface terminals 232 is five, and the number of the second main surface terminals 233 is eight. When the number of terminals is reduced, the area that the first main surface terminals 232 occupy on the first main surface and the area that the second main surface terminals 233 occupy on the second main surface can be reduced.

Also, according to the piezoelectric filter of the second embodiment, the piezoelectric resonators 231b and 231d, which are series resonators, and the piezoelectric resonators 231a, 231c, and 231e, which are parallel resonators, are formed on the first substrate 210. Furthermore, the piezoelectric resonators 231f and 231h, which are series resonators, and the piezoelectric resonators 231g and 231i, which are parallel resonators, are formed on the second substrate 220. Also, series resonators are smaller in size than parallel resonators. By this means, the difference between the area that the piezoelectric resonators 231a to 231e occupy on the first main surface and the area that the piezoelectric resonators 231f to 231i occupy on the second main surface is reduced. That is, the piezoelectric resonators 231a to 231i can be formed on the first substrate 210 and the second substrate 220 in a good balance. As a result of this, it is possible to prevent unnecessary parts from being formed on the first main surface and the second main surface.

It should be considered that the embodiments disclosed herein are simply illustrative ones in all respects and are by no means limiting. The above-described embodiments may be omitted, substituted or modified in a variety of ways without departing from the scope and spirit of the accompanying claims.

Although cases have been described with the above embodiments where the piezoelectric resonators are BAW resonators, the present disclosure is by no means limited to this. For example, the piezoelectric resonators may be SAW (Surface Acoustic Wave) resonators.

Although ladder circuits of eighth order and ninth order have been described with the above embodiments, the present disclosure is by no means limited to this. The order of a ladder circuit according to the present disclosure may be 3 or greater. The order of a ladder circuit may be an even number or an odd number. That is, a ladder circuit of Nth order (where N is 3 or greater), including N piezoelectric resonators, may be used. In this case, the piezoelectric resonators of first order to Mth order (where M is an integer from 1 to N−1, inclusive) included in the ladder circuit may be formed on the first main surface of the first substrate, and (M+1)th-order to Nth-order piezoelectric resonators included in the ladder circuit may be formed on the second main surface of the second substrate. If the integer N is an even number, the integer M may be N/2. If the integer N is an odd number, the integer M can be (N−1)/2 or (N+1)/2.

What is claimed is:

1. A piezoelectric filter comprising:
a first substrate having a first main surface;
a second substrate having a second main surface facing the first main surface; and
a ladder circuit of Nth order, including N piezoelectric resonators, N being an integer of 3 or greater,
wherein first-order to Mth-order piezoelectric resonators included in the ladder circuit are formed on the first main surface, M being an integer from 1 to N−1, inclusive, and
wherein (M+1)th-order to Nth-order piezoelectric resonators included in the ladder circuit are formed on the second main surface.

2. The piezoelectric filter according to claim 1, wherein the integer N is an even number, and the integer M is N/2.

3. The piezoelectric filter according to claim 1, wherein the integer N is an odd number, and the integer M is (N−1)/2 or (N+1)/2.

4. The piezoelectric filter according to claim 1, wherein, in plan view normal to the first main surface, the piezoelectric resonators formed on the first main surface and the piezoelectric resonators formed on the second main surface have an overlapping part.

5. The piezoelectric filter according to claim 1, wherein the piezoelectric resonators are bulk acoustic wave resonators.

6. The piezoelectric filter according to claim 1, wherein the piezoelectric filter is a bandpass filter.
